(19) United States
(12) Patent Application Publication
(10) Pub. No.: US 2012/0211052 A1
(43) Pub. Date: Aug. 23, 2012

(54) PHOTOVOLTAIC STRIP SOLAR MODULES AND METHODS

(75) Inventors: Ajay MARATHE, Saratoga, CA (US); Douglas R. Battaglia, JR., Campbell, CA (US); Frank Magana, Aptos, CA (US); Raghunandan Chaware, Mountain View, CA (US)

(73) Assignee: Solaria Corporation, Fremont, CA (US)

(21) Appl. No.: 13/360,562

(22) Filed: Jan. 27, 2012

Related U.S. Application Data
(60) Provisional application No. 61/502,282, filed on Jun. 28, 2011.

(51) Int. Cl. H01L 31/052

(52) U.S. Cl. 136/246

(57) ABSTRACT

A light energy collection device includes a glass layer having light concentrators for receiving light and for concentrating concentrated light, the light concentrators are elongated and substantially parallel manner to a first edge of the glass layer, wherein pitches of the light concentrators vary along the length generally within the range of approximately 5.5-5.8 mm, strings of multiple PV strips extending in a parallel manner to a second edge (perpendicular to the first edge) of the glass layer, wherein a string of PV strips includes: electrodes extending substantially parallel to the second edge, PV strips electrically coupled to the electrodes and extending substantially parallel to the first edge, wherein pitches of the PV strips vary along their length according to varying pitches of the light concentrators, wherein the PV strips receive concentrated light and output electrical energy in response to the concentrated light.

### CROSS REFERENCE TO RELATED APPLICATIONS

This application claims priority to provisional application 61/502,282, filed Jun. 28, 2011, which is incorporated by reference for all purposes.

### BACKGROUND OF THE INVENTION

The present invention relates to photovoltaic energy sources. More particularly, the present invention relates to using photovoltaic (PV) modules to convert solar energy into electrical energy.

The inventor of the present invention has determined that a challenge with using PV strips for capturing solar energy is how to effectively direct and concentrate incident light/radiation to PV strips within a PV module. Another challenge is how to manufacture such solar concentrators with materials that can last the expected life span of a solar panel, or the like, e.g. over 20 years.

One possible solution considered by the inventor was with the use of a metal concentrator in front of PV strips within a PV module. Drawbacks to such solutions include that a metal concentrator would be bulky and would cause the thickness of the solar panel to increase greatly. Another drawback includes that exposed metal may corrode and lose reflecting capability as it ages.

Another possible solution, considered by the inventor, was the use of a thin clear, polycarbonate layer on top of the PV strips. In such configurations, a number of v-shaped grooves were molded into the polycarbonate layer that acted as prisms. Incident light to the prisms would thus be directed to PV strips located within the v-shaped grooves.

One possible drawback to such solutions considered by the inventor is the durability and longevity of such polycarbonate layers. More specifically, the long-term (20+ years) translucency (e.g. hazing, cracking), geometric property stability (e.g. shrink-free), or the like cannot be predicted with certainty.

Accordingly, what is desired are improved concentrator apparatus and methods for tuning placement of PV strip with respect to the concentrator and for manufacturing a PV panel.

### BRIEF SUMMARY OF THE INVENTION

The present invention relates to photovoltaic energy sources. More particularly, the present invention relates to using photovoltaic (PV) modules to convert solar energy into electrical energy.

According to various embodiments of the present invention, incident light concentrators are manufactured from a transparent (e.g. substantially transparent) or translucent material (e.g. glass, acrylic) and are placed adjacent to PV strips of a PV module. In various embodiments, a sheet of material, e.g. glass, or other transparent material, is extruded or impressed to have a cross-section including a series semicircular shaped regions. In operation, each semicircular-shaped region acts as a solar concentrator to redirect sun light, e.g. parallel light, towards a smaller region on the surface opposite of the semicircular-shaped region. Various physical adjustments may be made on the PV strips relative to the translucent material to account for non-uniformities in the semicircular shaped regions.

In various embodiments, the geometric concentration characteristics of a semicircular-shaped region is characterized based upon a parallel light source and light detector along its length. This characterization is repeated for multiple semicircular-shaped regions on the concentrator sheet.

In various embodiments, the characterization data may be used as input for a PV strip placement operation with respect to the sheet of material. For example, such characterization data may be used by a user to determine where to place a PV strip relative to the sheet of material in an x and y direction, as well as a θ direction. As another example, such characterization data may be used by a machine or device that can pick PV strips and accurately position the PV strip relative to the sheet of material. In various embodiments, the placement of the PV strip relative to the sheet of material maximizes the capture of solar light by the PV strip. In other embodiments, the placement allows a wider angle of incidence of solar light striking the PV panel that is captured by the PV strips. Additionally, in various embodiments, the placement may be modified based upon physical properties such as: conductive bus bar expansion and contraction, reflow of material during a lamination step, or the like

In various embodiments, PV strips are electrically coupled to form a PV assembly (e.g. 12, 14, 24 PV strips). In turn, multiple PV assemblies are electrically coupled to form a PV string (e.g. 12, 14 PV assemblies). In various embodiments, the IV characteristics of PV strings are determined via dark field testing. Based upon the determined IV characteristics, PV strings may matched prior to incorporation into a finished PV module. In particular, PV strips that have similar IV characteristics are connected to reduce electrical stress (e.g. mismatch) upon the PV strips. In various embodiments 12 to 14 PV strings may then be electrically connected with conductors/bussing. In turn, the interconnected PV strings are sandwiched within a layered PV structure including the sheet of glass (e.g. transparent material), one or more adhesive materials, and the like. The PV structure is then subject to a controlled pressure lamination process to form the completed PV panel (PV module).

Previously, with solar panels, much emphasis has been placed upon uniformity. For example, uniform placement of solar wafers within a solar panel, uniform placement of solar cells within a mirror concentrator, and the like. The inventors of the present invention has discovered that uniformity is not always desirable. Further, the inventors have discovered that by modifying placement locations of PV strips within a PV assembly or PV string may desirable. For example, by determining variations in physical properties of solar concentrators, locations of PV strips may be placed in expressly non-uniform locations. Unexpectedly, the inventors have realized an solar efficiency increase of a PV panel manufactured according to embodiments described herein. Further, the inventors have realized a greater angle of incidence capability of such a PV panel. Accordingly, embodiments described herein provide unexpected benefits.

According to one aspect of the invention, a light energy collection device is disclosed. One device includes a transparent material having a plurality of light concentrating geometric features, wherein the plurality of light concentrating geometric features are configured to receive incident light and configured to output concentrated light at an associated plurality of exitant regions, the plurality of concentrating geometric features configured in a plurality of elongated structures arranged in a substantially parallel manner along a first direction from a first end to a second end of the transparent material, wherein at least two adjacent exitant regions are characterized by a non-uniform exitant pitch along the first direction, wherein the non-uniform exitant pitch varies from approximately 5.5 mm to approximately 5.8 mm along the first direction. A device may include a non-uniform string of two or more photovoltaic strips, wherein the non-uniform string extends in a second direction from a third end to a fourth end of the transparent material, wherein the second direction is approximately orthogonal to the first direction, and wherein the non-uniform string that includes: a plurality of conductive electrodes arranged in a substantially parallel manner along the second direction of the transparent material; and a plurality of photovoltaic strips coupled to the plurality of conductive electrodes, wherein the plurality of photovoltaic strips are approximately oriented along the first direction, and wherein adjacent photovoltaic strips are characterized by a non-uniform photovoltaic strip pitch along the first direction in response to the non-uniform exitant pitch. In various embodiments, the plurality of photovoltaic strips of the non-uniform string of the two or more photovoltaic strips are configured to receive the concentrated light from the plurality of light concentrating geometric features and configured to output electrical energy in response to the concentrated light.

According to another aspect of the invention, a light energy collection device is disclosed. One device includes a transparent material having a plurality of light concentrating geometric features comprising a top surface configured to receive incident light and a bottom surface configured to output concentrated light at a plurality of exitant regions, wherein the plurality of light concentrating geometric features comprise elongated structures arranged in a substantially parallel manner along a first axis relative to the transparent material, wherein a first exitant region and a second exitant region from the plurality of exitant regions are characterized by an exitant separation pitch along a second axis relative to the transparent material, that is non-uniform along the first axis, wherein the exitant separation pitch varies by no more than approximately 5% from a nominal separation pitch, and wherein the first axis is approximately orthogonal to the second axis. A device may include a string of two or more photovoltaic strips disposed below the transparent material, wherein the string extends along the second axis relative to the transparent material. In some embodiments, the string may include a plurality of conductive electrodes arranged in a substantially parallel manner along the second axis of the transparent material, and a plurality of photovoltaic strips coupled to the plurality of conductive electrodes, wherein the plurality of photovoltaic strips are approximately oriented along the first axis, and wherein a first photovoltaic strip and a second photovoltaic strip from the plurality of photovoltaic strips are characterized by a PV separation pitch along the second axis relative to the transparent material, that is non-uniform along the first axis, and in response to the exitant separation pitch. In some embodiments, the plurality of photovoltaic strips are positioned to receive the concentrated light and output electrical energy in response thereto.

### BRIEF DESCRIPTION OF THE DRAWINGS

In order to more fully understand the present invention, reference is made to the accompanying drawings. Understanding that these drawings are not to be considered limitations in the scope of the invention, the presently described embodiments and the presently understood best mode of the invention are described with additional detail through use of the accompanying drawings in which:

FIGS. 1A-B illustrate various aspects according to embodiments of the present invention;

FIGS. 2A-C illustrate block diagrams of processes according to various embodiments of the present invention;

FIGS. 3A-E illustrate examples according to various embodiments of the present invention;

FIG. 4 illustrates a block diagram of a computer system according to various embodiments of the present invention;

FIG. 5 illustrates various embodiments of the present invention;

FIG. 6 illustrates an apparatus according to various embodiments of the present invention; and

FIG. 7 illustrates an example according to various embodiments of the present invention.

### DETAILED DESCRIPTION OF THE INVENTION

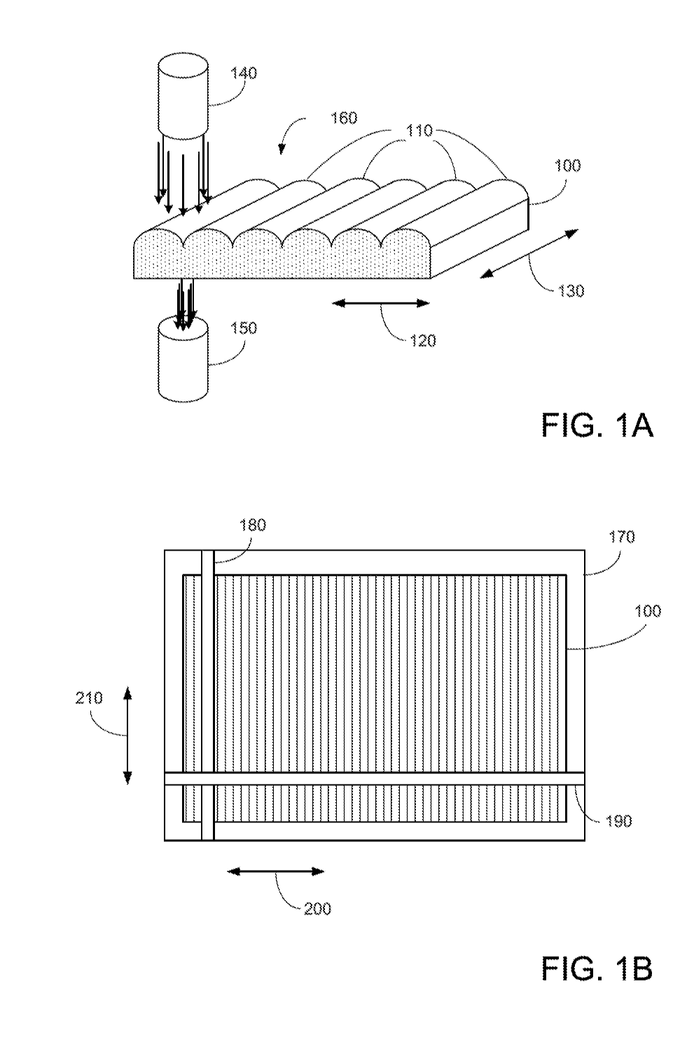

FIGS. 1A-B illustrate various aspects according to embodiments of the present invention. More specifically, FIGS. 1A-B illustrate an apparatus for determining concentration characteristics of a sheet of material 100.

In FIG. 1A, an embodiment of a sheet of transparent (substantially transparent) material 100 is shown. In some embodiments, the sheet may be translucent. As can be seen, sheet 100 may include a number of concentrating elements 110 in a first direction 120. In one example, there are approximately 175 concentrating elements across sheet 100, although in other examples, the number of concentrating elements may vary. In various examples, the nominal pitch of concentrating elements 110 ranges from approximately 5.5 mm to 6 mm. In other embodiments, the nominal pitch may be 5.74+/−0.2 mm, 7.0+/−0.2 mm, or the like. In various embodiments, as the nominal pitch increases, fewer PV strips, described below, are required for PV assemblies or PV strings.

In various embodiments, sheet 100 may be manufactured as a sheet of extruded material, accordingly, the concentrating elements may extend in a second direction 130, as shown. In other embodiments, the concentrating elements may vary in second direction 130. In other embodiments, sheet 100 need not be extruded, but may be impressed with a pattern while in a molten or liquid state, or the like.

In various embodiments of the present invention, a light source 140 and a light detector 150 may also be provided. In various embodiments, light source 140 may provide collimated light to the surface 160 of material 100 having concentrating elements 110. In various embodiments, light source 140 may include LED lights, stroboscopic lights, laser, or the like. In other embodiments, the Sun may be used as light source 140. In some embodiments of the present invention, light source 140 may provide specific ranges of wavelengths of light, e.g. infrared, ultraviolet, reddish, greenish, or the like, depending upon the wavelength sensitivity of PV strip. In general source 140 may provide any type of electromagnetic radiation output, and detector 150 may sense such electromagnetic radiation.

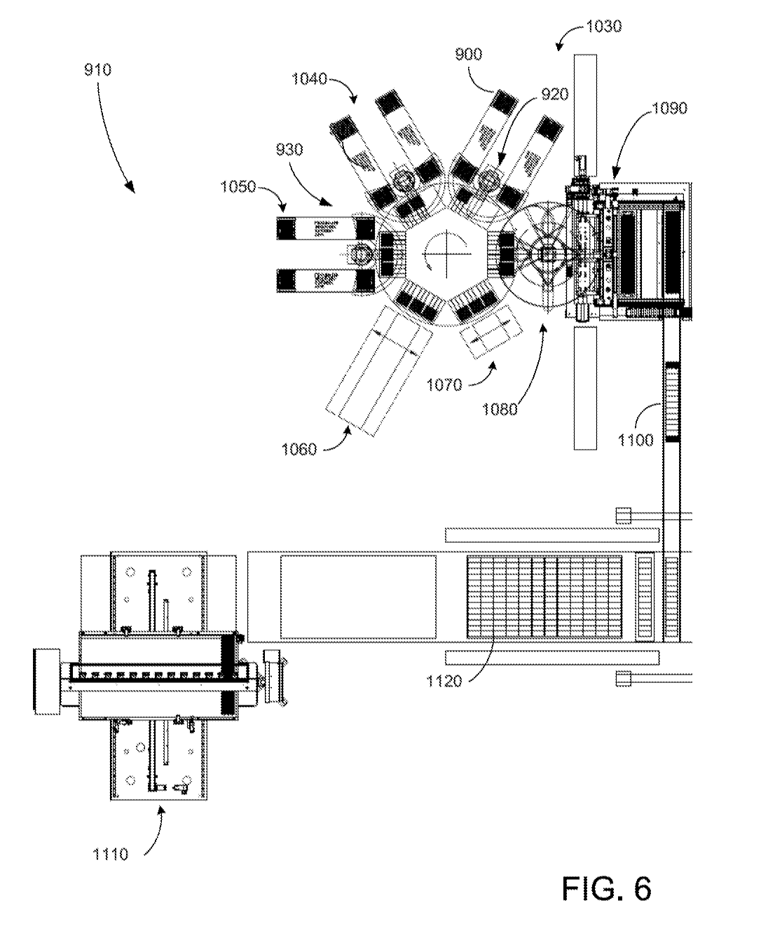

In various embodiments, light detector 150 comprises a photo detector, such as a CCD, a CMOS sensor, or the like. In operation, light detector 150 may be a two-dimensional sensor and may provide an output proportional to the intensity of light incident upon each light sensor of light detector 150. In other embodiments, as illustrated in FIG. 6, multiple photo detectors and multiple light sources may be used in parallel. For example, in some embodiments, from 11 to 13 light sources and light sensors are configured in a single row.

FIG. 1B illustrates another view of an embodiment of the present invention. In this figure, sheet 100 is show from the top or bottom. As shown, sheet 100 is mounted upon a frame assembly 170. In some embodiments, sheet 100 may be supported merely by a frame portion of frame assembly 170, whereas in other embodiments, frame assembly 170 may include a piece of transparent material, e.g. glass to support sheet 100.

In FIG. 1B, a first movement arm 180 and a second movement arm 190 are shown. In various embodiments, first movement arm 180 may be constrained to move in a first direction 200, and second movement arm 190 may be constrained to move in a second direction 210. It is contemplated that first movement arm 180 and second movement arm 190 may be precisely be positioned within first direction 200 and second direction 210, respectively.

In various embodiments of the present invention, light source 140 is positioned at the intersection of first movement arm 180 and second movement arm 190. In operation, the location of light source 140 on top of sheet 100 is precisely controlled by the positioning of first movement arm 180 and second movement arm 190. In various embodiments, the accuracy of positioning of light source 140 is +−10 microns, although they may vary in other embodiments.

A similar set of movement arms are typically provided on the opposite side of sheet 100, as shown in FIG. 1A. In various embodiments, light detector 150 is also positioned at the intersection of these movement arms. In operation, light source 140 and light detector 150 are typically precisely positioned on opposite sides of sheet 100, as will be described below.

In other embodiments of the present invention, other types of positioning mechanisms may be used. For example, a single arm robotic arm may be used to precisely position light source 140 and a single robotic arm may be used to precisely position light detector 150.

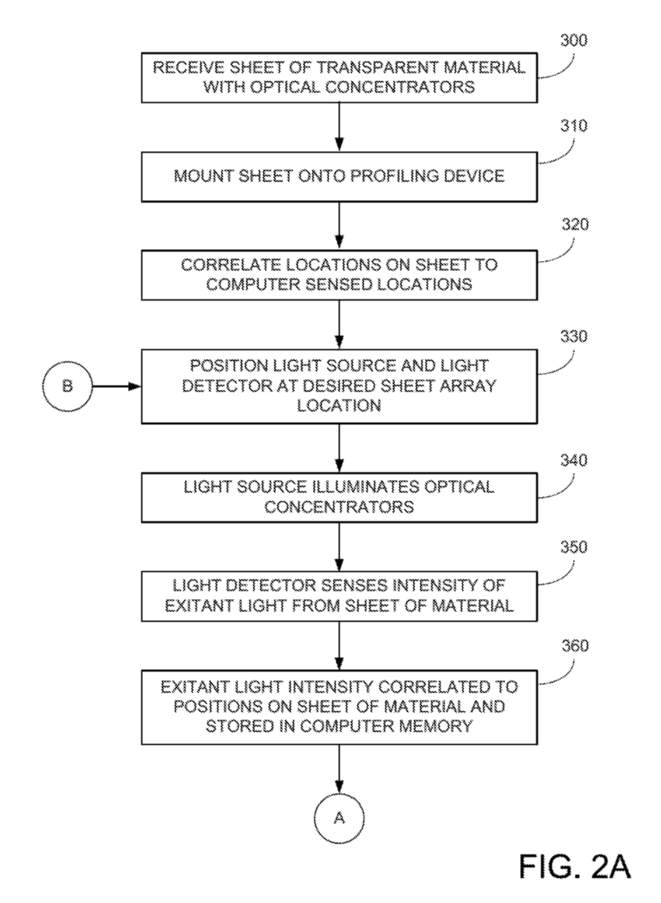

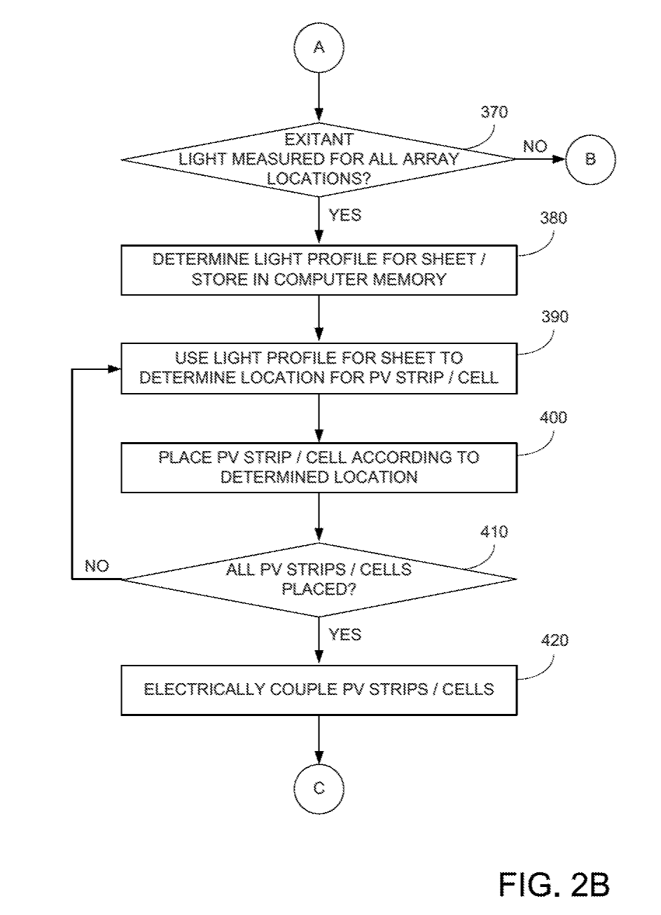

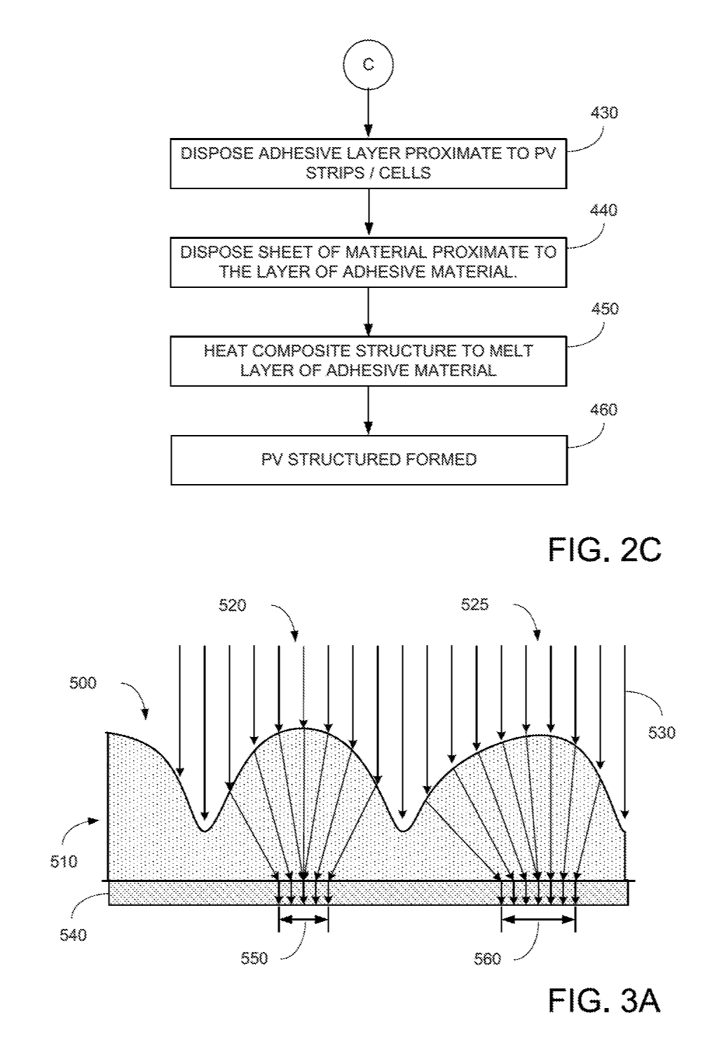

FIGS. 2A-C illustrate a block diagram of a process according to various embodiments of the present invention. For sake of convenience, reference may be made to elements illustrated in FIGS. 1A-B.

Initially, sheet 100 is provided, step 300. In various embodiments, sheet 100 may be made of various grades and qualities of glass, plastic, polycarbonate, translucent material, or the like. In various embodiments, sheet 100 includes any number or type of concentrators 110, that may be integrally formed within sheet 100. In some case, sheet 100 may be formed from an extrusion process, a molding process, a grinding/polishing process, or a combination thereof.

Next, sheet 100 is mounted upon supporting frame assembly 170, step 310. It is contemplated that sheet 100 is secured to frame assembly 170 so that the measurements performed may be accurate. In various embodiments, concentrators 110 may be faced downwards or faced upwards while mounted upon supporting frame assembly 170. As discussed above, frame assembly 170 may include a clear piece of glass, plastic, or the like to support the weight of sheet 100.

In various embodiments of the present invention, one or more calibration steps may then be performed to correlate locations on sheet 100 with the locations of light source 140 and light detector 160, step 320. For example, the corners of sheet 100 may be located in two-dimensions with respect to supporting frame assembly 170. In other embodiments, other types of calibration may be performed such as directly exposing light source 140 to light detector 150 so as to normalize the amount of light detected in the subsequent steps.

In normal operation, light source 140 and light detector 150 are positioned at a determined position, step 330. For example, if sheet 100 can be divided up into an array of locations, light source 140 and light detector 150 may be positioned at a desired location e.g. (0,0), (14,19), (32,32), or the like. In various embodiments, fiducial marks may be printed or marked upon sheet 100 to help determine positions of sheet 100 relative to light source 140 and light detector 150. Next, as light source 140 illuminates the side of sheet 100 including concentrating structures 110, step 340. In various embodiments, light source 140 provides a substantially calumniated beam of light using lasers, LEDs, or the like. Next, light detector 150 records the intensity of light exiting the other side of sheet 100, step 350. In various embodiments, photo diodes, or the like may be used for light detector 150.

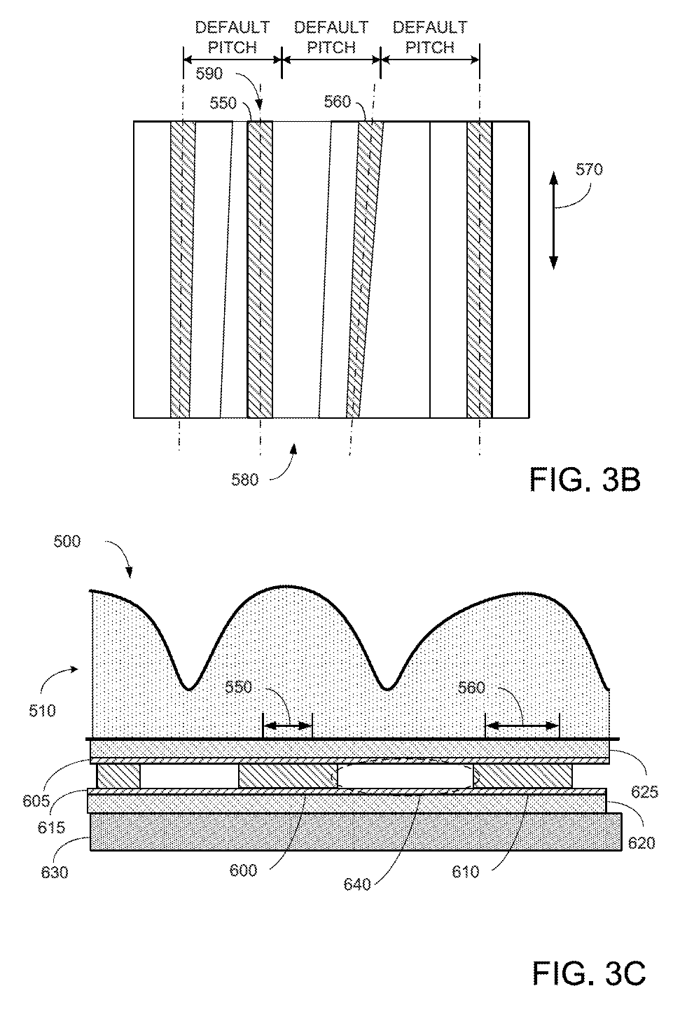

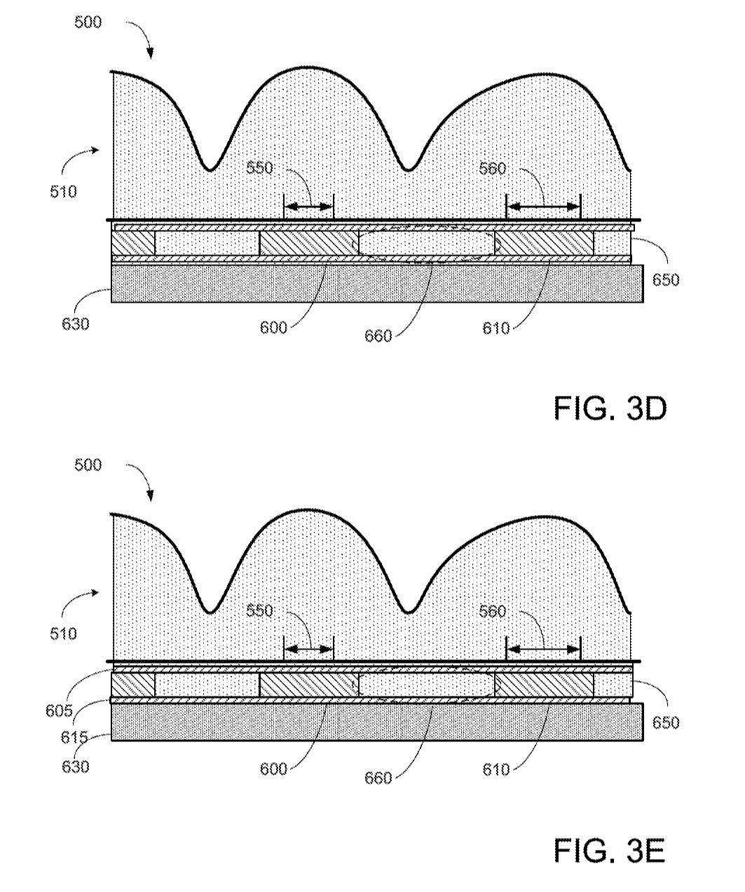

In various embodiments of the present invention, light detector 150 records the exitant light from portions of one or more concentrators 110. For example, the field of view of light detector 150 may record the concentration of one concentrator 110, as illustrated in FIG. 1B, or more concentrators 110. In various embodiments, as illustrated in FIGS. 3A-B, exitant light beams 550 and 560, and concentrated light regions 590 may vary along in width between adjacent lenses and along the extrusion axis 570. In various embodiments, a center line of exitant beams 550 and 560 and concentrated light regions 590 are subsequently determined, using various operations, or the like, and the center line locations are recorded. The inventor has experimented with other methods for placing PV strips relative to concentrators 110, for example, based upon troughs, however these techniques did not account for the geometric variations of the concentrator itself across sheet 100.

In various embodiments, operations for determining center line locations are contemplated. Some embodiments include determining a peak light intensity for the exitant light across sheet 100 to be used as a center-line location. Other embodiments includes mathematically recording the exitant light intensity versus movement dimension, the result which often appears similar to a bell-shaped curved. Based upon the two-dimensional bell-shaped curve, a center of gravity is determined which is then used as the center-line location. In other embodiments, a thresholding level may be used upon the exitant light intensity data to determine two locations for a light peak where the intensity (e.g. voltage) equals the threshold level (e.g. one volt). The mathematical average of these two locations can thus be used as the center-line location. In other embodiments of the present invention, many other ways for determining a center-line location are also contemplated. As mentioned above, determination of the center-line helps to maximize the power production of the PV strip, and/or also helps maximize the range of angles of incidence (AOI) for the incident illumination (e.g. sun light).

In various embodiments of the present invention, a thin sheet of translucent/opaque material, e.g. EVA, PVB, Surlyn, thermosets material, thermoplastic material, or the like, may be disposed upon sheet 100 on the side facing light detector 150. In such embodiments, the thin sheet of material facilitates optical detection of the exitant illumination. More specifically, the locations/contours and intensity of the exitant illumination become more apparent to light detector 150 because of the diffusing properties of the material as provided by the manufacturer. In later lamination steps (heat, pressure, time) that will be described below, the diffusing properties of the thin material are greatly reduced and the thin material becomes more transparent. In other embodiments the thin sheet of material may be parchment material, or the like.

In various embodiments, the detected illumination data are correlated to the array location of sheet 100 and then stored in a computer memory, step 360. In some embodiments, light detector 150 may capture and provide one or more frames of illumination data. In such embodiments, an average of the multiple frames of illumination may be used to reduce effects of spurious vibration of supporting frame assembly, transient vibrations due to movement of light source 140 and light detector 150, or the like.

In various embodiments, if the illumination data has not been captured for all array locations, step 370, the process above may be repeated for additional array locations.

Next, in various embodiments of the present invention, the stored illumination data and the array location data are used to determine an exitant light profile for sheet 100, step 380. More specifically, the light profile may include an intensity of light and an x, y coordinate for sheet 100.

In various embodiments of the present invention, based upon the exitant light profile, image processing functions may be performed to determine positioning data for placement of PV strips, step 390. For example, center of gravity or morphological thinning operations may be performed to determine one or more center-lines for placement of the PV strips, edge contouring operations may be performed to provide an outline for placement of the PV strips, or the like. This positioning data may also be stored in computer memory. In various embodiments, after determining the one or more center-lines for placement of the PV strips, sheet 100 may also be optically marked with fiducials indicating the center-lines.

In some embodiments of the present invention, it is contemplated that the width of concentrated light by concentrators 110 is smaller than the narrow width of PV strips. Accordingly, in some embodiments, the concentrated light should be centered within the PV strips. It is contemplated that this would increase, e.g. maximize the collection of light of a given PV strip relative to the exitant light, and/or increase the angle of incidence (AOI). In various embodiments, a large angle of incidence (AOI) means that incident light from a larger range of angles relative to a normal of the solar panel will be concentrated upon the PV strips. In various embodiments, a typical PV strip may be on the order of approximately 2.5 mm, 2.83 mm, 3.12 mm, or the like. Further, the typical width of concentrated light is on the order of approximately 0.8 to approximately 1 mm. Accordingly, when incident light is approximately normal to the solar panel, the concentrated light will be directed towards the center of the PV strips, and approximately 0.75 mm spacing of the PV strip to the right and left of the concentrated light will not be illuminated. When the incident light is not normal to the solar panel, the concentrated light may move to the right and/or left of the center of the PV strip. In light of the present disclosure, by using a wider PV strip, the AOI may be increased.

Next, if not already placed upon sheet 100, a thin sheet of translucent/opaque backing material, e.g. EVA, PVB, Surlyn, thermosets material, thermoplastic material, or the like, may be placed upon sheet 100. The positioning data determined above (e.g. center-lines) may then be used by a user, or the like, to place PV strips on a backing material, step 400. In some embodiments, the positioning data, e.g. the center-lines, may be printed upon backing material, or the like, along with corner registrations. Based upon such positioning data, a user may manually place the PV strips or PV cell (groups of PV strips e.g. PV assembly, PV string, PV module) approximately along the center-lines, or the like. In other embodiments, the positioning data may be input into a robotic-type pick and place machine that picks up one or more PV strips or PV cells and places them down on a backing material, a vacuum chuck, or the like at the appropriate locations. In various examples, placement accuracy may be +/−10 to 15 microns, although these may vary in other embodiments. In various embodiments, an adhesive material, e.g. EVA, PVB, Surlyn, thermosets material, thermoplastic material or the like, may be disposed between the PV strips and the backing material.

In other embodiments of the present invention, the PV strips may be placed upon the thin layer of diffusing material described above, e.g. EVA, PVB, Surlyn, thermosets material, thermoplastic material or the like, that is placed upon the back side of sheet 100, e.g. opposite of concentrators 110.

The process may then repeat for placement of the next PV strip or PV cell, step 410, until all the desired PV strips or PV cells have been placed.

Subsequently, a soldering step may be performed to electrically couple and physically restrain one or more PV strips relative to other PV strips or one or more PV cells relative to other PV cells, step 420.

In various embodiments, a layer of adhesive material is disposed upon the soldered PV strips or PV cells, step 430. In some embodiments, the layer of adhesive material such as ethylene vinyl acetate (EVA), Polyvinyl butyral (PVB), Surlyn, thermosets material, thermoplastic material or the like, may be used. Subsequently, sheet 100 is disposed upon the layer of adhesive material, step 440. In various embodiments, any number of registration marks, or the like may be used so that sheet 100 is precisely disposed above the PV strips or PV cells. More specifically, sheet 100 should be aligned such that the PV strips are positioned at the proper positions or locations under the respective concentrators 110.

In other embodiments, sheet 100 is provided, and the layer of adhesive material is placed on top of sheet 100. In this configuration, the light profiles described in steps 300-380 may be performed. Next, PV strip placement and electrical bussing of steps 390-420 may be performed at a separate location from the adhesive/sheet 100 structure, as illustrated in FIG. 6, below. Subsequently, the electrically connected PV strips are disposed upon the adhesive/sheet 100 structure, and another layer of adhesive layer is disposed upon the electrically coupled PV strips to form a composite structure In step 450, the composite structure is processed through a lamination process, to form the PV panel or PV module in step 460.

In other embodiments where the PV strips are placed upon the thin diffusing layer described above, upon sheet 100, in these steps, an additional layer of material (e.g. EVA, PVB, Surlyn, thermosets material, thermoplastic material or the like may be placed upon the PV strips, and then a backing material may be placed upon the additional adhesive layer. Accordingly, in some embodiments, the composite PV structure is formed by building on top of sheet 100, and in other embodiments, the composite PV is formed by building on top of the backing material.

In various embodiments, the resulting sandwich of materials is bonded/laminated in an oven set to a temperature above approximately 200 degrees Fahrenheit, step 450. More specifically, the temperature is typically sufficient for the adhesive layer (e.g. EVA, PVB, Surlyn, thermosets material, thermoplastic material or the like) to melt (e.g. approximately 150 degrees C.) and to bond: the PV strips or PV cells, the backing, and sheet 100 together. In some embodiments, in addition to bonding the materials together, as the adhesive (e.g. EVA, PVB, Surlyn, thermosets material, thermoplastic material or the like) melts, it occupies regions that were formerly gap regions between adjacent PV strips or PV cells. This melted adhesive helps prevent PV strips from moving laterally with respect to each other, and helps maintain alignment of PV strips relative to sheet 100. Additionally, the adhesive material occupies regions that were formerly gap regions between bus bars between the PV cells. As will be discussed below, the time, temperature and pressure parameters for the lamination step may be advantageously controlled.

In various embodiments, one or more wires may be stung before and/or after the bonding step to provide electrical connection between the PV strips or PV cells. These wires thus provide the electrical energy output from the completed PV panel (PV module), step 460.

FIGS. 3A-E illustrate examples according to various embodiments of the present invention. More specifically, FIG. 3A illustrates a cross section 500 of a portion of a transparent sheet 510. As can be seen, a number of concentrators, e.g. 520 and 525 are illustrated.

In FIG. 3A, a number of parallel light rays 530 from a source of illumination are shown striking the air/material (e.g. glass) interface, and being directed towards regions 550 and 560 (regions having concentrated light). As discussed above, a sensor captures locations of concentrated light at regions 550 and 560 on transparent sheet 510. As shown in this example, a layer of diffusing material 540 may be placed adjacent to sheet 510 to help the sensor capture the locations of regions 550 and 560. As will be discussed below, in various embodiments, the layer of diffusing material 540 may also serve as an adhesive layer. More specifically, before a lamination process (e.g. FIG. 3C), the adhesive layer tends to diffuse incident light, and after the lamination process (e.g. FIGS. 3D and E), the adhesive layer tends to secure PV strips relative to the transparent material (e.g. glass) sheet, and tends to become relatively transparent.

As can be seen in this embodiment, concentrators are not typically the same size, shape, or pitch. In practice, it has been determined that the pitch of concentrators may vary across a sheet from 40 microns up to 500 microns. Further, the concentrators need not be symmetric. Accordingly, the regions where the light is concentrated may widely vary for different and even adjacent concentrators. As can be seen in this example, region 560 is off-center, and region 560 is wider than region 550. In other embodiments, many other differences may become apparent in practice.

As illustrated in FIG. 3B, the width, positioning, etc. of regions of concentrated light are not necessarily or typically uniform along the extrusion axis 570 of glass (e.g. transparent material) sheet 510. In this example, it can be seen that the width of the concentrators 580 may vary along extrusion axis 570, the width of the concentrated light regions 590 may vary along extrusion axis 570, the concentrated light region may be off-center, and the like. Accordingly, in various embodiments of the present invention, PV strips are displaced to the right or left relative to other PV strips, and are not at necessarily placed at a fixed pitch relative to other PV strips. Additionally, in various embodiments, the PV strips are not necessarily parallel to the edge of sheet 510, but may be placed at an angle similar to the angle of the exitant light beam, as shown by 560 in FIG. 3B.

In light of the above, it can be seen that because of the wide variability of concentrator geometry of transparent material sheet 500, proper placement of PV strips relative to the concentrated light regions is desirable.

In the example illustrated in FIG. 3C, PV strips 600 and 610 are illustrated disposed under regions 550 and 560 of FIG. 3B. In various embodiments, the width (e.g. 2.15 mm) of PV strips may be from approximately 25% to 50% wider than the width (e.g. 1.2 mm) of the concentrated light regions. In various embodiments, it is believed that if light that enters the concentrators at angles other than normal to sheet 510 (e.g. 3 to 5 degrees from normal, or greater), the light may still be incident upon the PV strips. In current examples, the width of the concentrated light regions ranges from approximately 1.8 mm to 2.2 mm, although other width region ranges are also contemplated. For example, as the quality control of sheet 510 including geometric uniformity and geometric preciseness of concentrators, clarity of the transparent material (e.g. glass), or the like increase, the width of the concentrated light regions should decrease, e.g. with a lower width of approximately 0.25 mm, 0.5 mm, 1 mm, or the like.

As illustrated in FIG. 3C, PV strips 600 and 610 are adjacent to transparent material sheet 500 and a backing layer 630 via adhesive layers 620 and 625. As can be seen, in various embodiments, first adhesive layer 620 may be disposed between PV strips (600 and 610) and backing layer 630, and a second adhesive layer 625 may be disposed between PV strips (600 and 610) and transparent material sheet 500. Further, gap regions, e.g. region 640, exist between adjacent bus bars 605 and 615 and between adjacent PV strips (600 and 610). In some current embodiments, the height between adjacent bus bars is typically smaller than 200 microns.

In FIG. 3D, the structure illustrated in FIG. 3C is subject to a precisely controlled lamination process. In the case of the adhesive layers being formed from layers of EVA, PVB, Surlyn, thermosets material, thermoplastic material or the like material, the first adhesive layer 620 and second adhesive layer 625 melt and reflow. As can be seen in FIG. 3D, first adhesive layer 620 and second adhesive layer 625 may mix together to form a single layer, as illustrated by adhesive layer 650. In such embodiments, voids between PV strips and bus bars, e.g. gap region 640 before lamination process, are then filled (region 660) by the adhesive material, e.g. EVA, after the lamination process. In various embodiments, the adhesive material adheres to the PV strips and/or bus bars. As a result, PV strips 600 and 610 are not only secured relative to transparent material sheet 500 and backing layer 630, but are also laterally secured with respect to each other by the reflowed EVA material. Additionally, the preexisting separation between bus bars 605 and 615 are maintained. In various embodiments, the adhesive material acts as a barrier to reduce solder shorts between neighboring PV strips and/or neighboring bus bars, for example, as a result of a user pushing down upon bus bars connecting PV strips. Further, the adhesive material acts as a barrier to moisture, corrosion, contaminants, and the like. In other embodiments of the present invention, a single adhesive layer may be used, as illustrated in FIG. 3E.

In various embodiments of the present invention, the lamination process includes precisely controlled time, temperature and. or physical compression variable profiles. In one example, the compression pressure pressing down upon the stack of materials ranges from approximately 0.2 to 0.6 atmospheres. In various embodiments, the lamination pressure profile includes subjecting the structure illustrated in FIG. 3C to a compression pressure of approximately 25 kPA (e.g. ¼ atmosphere) for about 25 seconds followed by a pressure of approximately 50 kPA (e.g. ½ atmosphere) for about 50 seconds. During this time period, the EVA material, or the like is heated to the melting point, e.g. approximately greater than 150 degrees C., or greater, depending upon the melting point of the specific type of adhesive material.

Experimentally, the inventors have determined that if the lamination process is performed under a compression pressure of approximately 1 atm, as the adhesive material, e.g. EVA, melts and reflows, gap regions remain between adjacent PV strips and remain between bus bars between adjacent PV strips, as described above. In other embodiments of the present invention, other combinations of time, temperature and compression pressure may be determined that provide the benefits described above, without undue experimentation by one of ordinary skill in the art.

In other embodiments of the present invention, when other adhesive materials such as PVB, Surlyn, thermosets material, thermoplastic material or the like are used, the time, temperature, pressure, and the like properties may be similarly monitored by the user such that the other adhesive materials perform a similar function as the EVA material, described above. More specifically, it is desired that the adhesive material fill the air-gap regions between the PV strips, and provide the protective and preventative features described above.

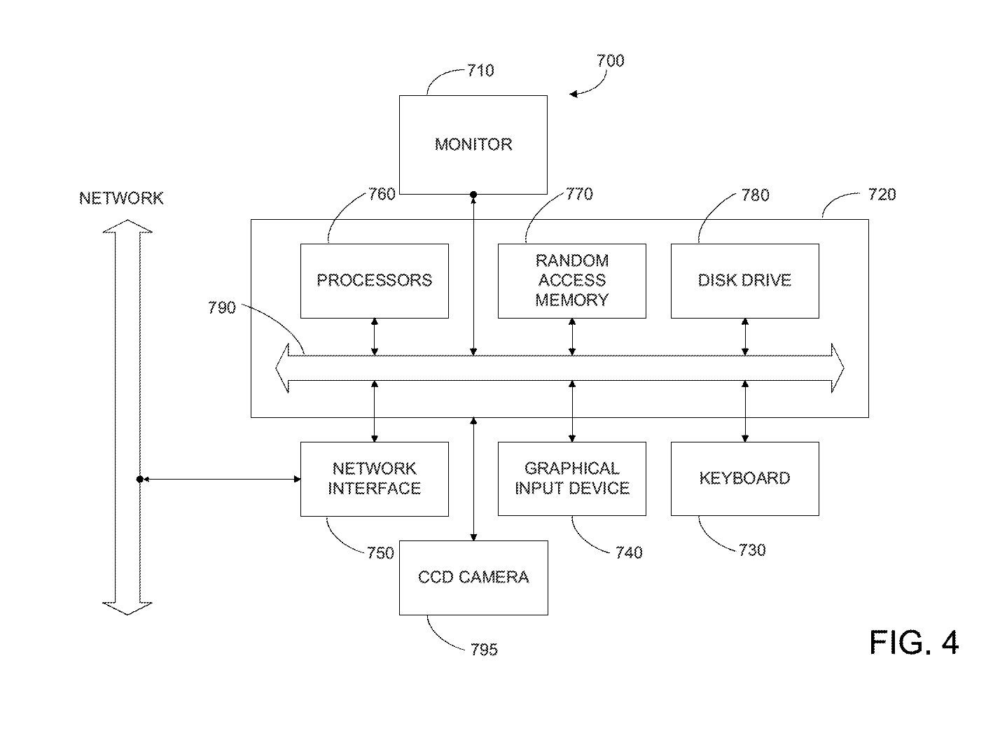

FIG. 4 illustrates a block diagram of a computer system according to various embodiments of the present invention. More specifically, a computer system 600 is illustrated that may be adapted to control a light source, a light detector, and/or a PV placement device, process data, control a lamination device, and the like, as described above.

FIG. 4 is a block diagram of typical computer system 700 according to various embodiment of the present invention. In various embodiments, computer system 700 typically includes a monitor 710, computer 720, a keyboard 730, a user input device 740, a network interface 750, and the like.

In the present embodiment, user input device 740 is typically embodied as a computer mouse, a trackball, a track pad, wireless remote, and the like. User input device 740 typically allows a user to select objects, icons, text, control points and the like that appear on the monitor 710. In some embodiments, monitor 710 and user input device 740 may be integrated, such as with an interactive touch screen display or pen based display such as a Cintiq marketed by Wacom, or the like.

Embodiments of network interface 750 typically include an Ethernet card, a modem (telephone, satellite, cable, ISDN), (asynchronous) digital subscriber line (DSL) unit, and the like. Network interface 750 is typically coupled to a computer network as shown. In other embodiments, network interface 750 may be physically integrated on the motherboard of computer 720, may be a software program, such as soft DSL, or the like.

Computer 720 typically includes familiar computer components such as a processor 760, and memory storage devices, such as a random access memory (RAM) 770, disk drives 780, and system bus 790 interconnecting the above components.

In one embodiment, computer 720 may include one or more PC compatible computers having multiple microprocessors such as Xeon™ microprocessor from Intel Corporation. Further, in the present embodiment, computer 720 may include a UNIX-based operating system. RAM 770 and disk drive 780 are examples of tangible media for storage of non-transient: images, operating systems, configuration files, embodiments of the present invention, including computer-readable executable computer code that programs computer 720 to perform the above described functions and processes, and the like. For example, the computer-executable code may include code that directs the computer system to perform various capturing, processing, PV placement steps, or the like, illustrated in FIGS. 2A-C; code that directs the computer system to perform controlled lamination process, or the like, illustrated in FIGS. 3C-D; any of the processing steps described herein; or the like.

Other types of tangible media include floppy disks, removable hard disks, optical storage media such as CD-ROMS, DVDs, Blu-Ray disks, semiconductor memories such as flash memories, read-only memories (ROMS), battery-backed volatile memories, networked storage devices, and the like.

In the present embodiment, computer system 700 may also include software that enables communications over a network such as the HTTP, TCP/IP, RTP/RTSP protocols, and the like. In alternative embodiments of the present invention, other communications software and transfer protocols may also be used, for example IPX, UDP or the like.

FIG. 4 is representative of computer systems capable of embodying the present invention. It will be readily apparent to one of ordinary skill in the art that many other hardware and software configurations are suitable for use with the present invention. For example, one or more computers may cooperate to perform the functionality described above. In another example, computers may use of other microprocessors are contemplated, such as Core™ or Itanium™ microprocessors; Opteron™ or Phenom™ microprocessors from Advanced Micro Devices, Inc; and the like. Additionally, graphics processing units (GPUs) from NVidia, ATI, or the like, may also be used to accelerate rendering. Further, other types of operating systems are contemplated, such as Windows® operating system such as Windows7®, WindowsNT®, or the like from Microsoft Corporation, Solaris from Oracle, LINUX, UNIX, MAC OS from Apple Corporation, and the like.

In light of the above disclosure, one of ordinary skill in the art would recognize that many variations may be implemented based upon the discussed embodiments. For example, in one embodiment, a layer of photosensitive material approximately the same size as the transparent material sheet described above is disposed under the sheet of transparent material. Subsequently, the combination is exposed to sun light. Because the material is photosensitive, after a certain amount of time, regions where the light is concentrated may appear lighter or darker than other regions under the transparent material (e.g. glass) sheet. In such embodiments, the material can then be used as a visual template for placement of the PV strips or cells. More specifically, a user can simply place PV strips at regions where the light is concentrated. Once all PV strips are placed, the photosensitive material may be removed or be used as part of the above-mentioned backing. As can be seen in such embodiments, a computer, a digital image sensor, a precise x-y table, or the like are not required to practice embodiments of the present invention.

In other embodiments of the present invention, a displacement sensor, e.g. a laser measurement device, a laser range finder, or the like may be used. More specifically, a laser displacement sensor may be used in conjunction with steps 300-380 in FIGS. 2A-B. In such embodiments, the measured and determined light profile of step 380 is determined, as discussed above. In addition, a laser displacement sensor may be used to geometrically measure the surface of the sheet of substantially transparent material, e.g. glass. It is contemplated that a precise measured geometric surface of the transparent sheet is then determined. In some embodiments of the present invention a Keyence LK CCD laser displacement sensor, or the like can be used.

In such embodiments, the measured geometric model of the transparent sheet and the determined light profile are then correlated to each other. In various embodiments, any number of conventional software algorithms can be used to create a computer model of the transparent material. This computer model that correlates as input, a description of a geometric surface and then outputs a predicted exitant light location. In various embodiments, a number of transparent sheets may be subject to steps 300-380 to determine a number of light profiles, and subject to laser measurement to determine a number of measured geometric surfaces. In various embodiments, the computer model may be based upon these multiple data samples.

Subsequently, in various embodiments of the present invention, a new transparent sheet may be provided. This new transparent sheet would then be subject to laser measurement to determine the measured geometric surface. Next, based upon the measured geometric surface and the computer model determined above, the computer system can then predict the locations of exitant illumination from the new transparent sheet. In various embodiments, steps 390-460 may then be performed using the predicted exitant illumination locations.

In other embodiments of the present invention, other types of measurement devices may be used besides a laser, such as a physical probe, or the like.

In other embodiments of the present invention, PV strips may be placed on top of an EVA layer, or the like directly on the bottom surface of the concentrators. These materials may then be subject to heat treatment, as described above. Accordingly, in such embodiments, a rigid backing material may not be needed. In still other embodiments, a light source may be an area light source, a line light source, a point light source, or the light. Additionally, a light may be a 2-D CCD array, a line array, or the like.

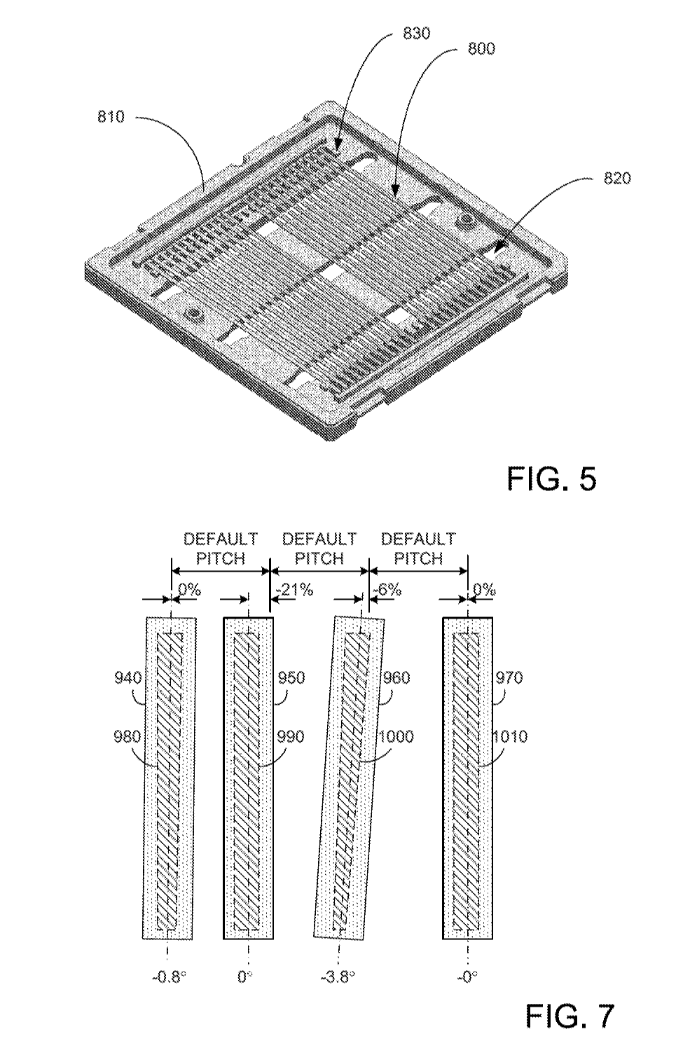

FIG. 5 illustrate various embodiments of the present invention. More specifically, FIG. 5 illustrate PV strips. In FIG. 5, a series of PV strips 800 are illustrated positioned in a PV carrier 810. In various embodiments, PV carrier 810 includes a number of physical guides that help position PV strips 800 at a desired spacing or pitch. In various embodiments, the nominal pitch is based upon the nominal pitch of concentrating elements 110 on sheet 100, for example, the nominal pitch may be 5.80 mm, 6.00 mm, 5.00 mm. In other embodiments, the nominal pitch may be independent of the nominal pitch of concentrating elements 100, and is determined by robotic PV strip pick and place elements, described further below.

As can be seen in FIG. 5, openings 820 are provided in PV carrier 810. In some embodiments, during the manufacturing process, one or more conductors may be laid across some or all of PV strips 800 in the direction of openings 820, and then the PV strips 800 are bar soldered to the conductors, to form a PV assembly. In various embodiments, half the number of PV strips 800 are used for form a PV assembly, such as 12 PV strips, 14 PV strips, or the like. In other embodiments, PV strips 800 are laid out and soldered together to form a PV assembly in different stages of the manufacturing process, as will be described below.

In FIG. 5, 24 PV strips 800 are illustrated, however in other embodiments, the number of PV strips 800 can vary, such as 12 PV strips, 14 PV strips, 28 PV strips, or the like. In various embodiments, PV strips 800 may be manually or automatically loaded into PV carrier 810. In various embodiments, PV carrier 810 may include any number of physical guides 830 that enable PV carriers to be physically stacked. For example, 8 to 10 PV carriers may be stacked to form a single compact stack for physical transport.

FIG. 6 illustrates an apparatus according to various embodiments of the present invention. In various embodiments, the stack of PV carriers 900 are inputs into an apparatus 910. As will be described below, PV strips stored within each PV carrier 900 are picked up by a pick and place robot 920 and placed in specified locations within a soldering station platform 930. In various embodiments, placement of the PV strips are determined based upon the positioning data determined in step 390 (e.g. center-line data). More specifically, based upon the exitant light profile and image processing operations, x and y locations as well as angle θ for each PV strip is determined. In other embodiments, control of the angle θ may be performed by moving the top edge of a PV strip left or right (e.g. +/−x direction) with regards to a bottom edge of a PV strip, moving the bottom edge with respect to the top edge, or moving the top edge and the bottom edge with respect to a point of rotation, or the like. In various embodiments device 1110 may be used to determine the exitant light profile.

FIG. 7 illustrates an example according to various embodiments of the present invention. In particular, FIG. 7 illustrates placement of PV strips 940-970 according to the example illustrated in FIG. 3B. Also illustrated, for sake of convenience, are the exitant light beams 980-1010 illustrated in FIG. 3B as well as the computed center lines. In particular, for PV strip 940, the left/right direction (e.g. x direction) offset is 0% (i.e. PV strip 940 is placed at the default pitch position), and is angled at −0.8° (e.g. bottom edge moved leftward, slightly); for PV strip 950, an x offset is −21%, but with no angle; for PV strip 960, an x offset is −6% and is angled −3.8° (e.g. bottom edge moved leftward); and for PV strip 970, no x offset and no angle adjustment are required from a default position. In various embodiments, other relative or absolute x and y positions or offsets may be used, e.g. mm, inches, or the like; and other measures for the angle may be used (e.g. x and y positions of the top edge relative to the bottom edge of the PV strip); or the like. As can be seen in this example, PV strips 940-970 are thus positioned to capture as much light as possible of extant light beams 980-1010.

In various embodiments of the present invention additional adjustments may be made to the PV strips prior to the soldering steps described below. In various embodiments of the present invention, the thermal expansion and contraction characteristics of the PV strips or the conducting crossbar in operation, are also expected to impart forces outwards from approximately the middle of a PV string towards the edges of the PV panel. Accordingly, in the example of FIG. 7, if PV strips 940 is to be located at the left edge of a PV panel, PV strip 940 may be adjusted from having a 0% offset to a +1% offset (e.g. rightwards by 20 microns), PV strip 950 may be adjusted from having a −21% offset to a −20% offset (e.g. rightwards 20 microns), or the like. In another example, if PV strip 970 is to be located at the right edge of a PV panel, PV strip 970 may be adjusted from having a 0% offset to a −1.5% offset (e.g. leftwards by 25 microns), PV strip 960 may be adjusted from having a −6% offset to a −7% offset (e.g. leftwards by 20 microns), or the like.

In experiments conducted using prototype assembly devices similar to that illustrated in FIG. 8, the change of pitch between exitant light beams illustrated in FIG. 7 are surprisingly smaller than expected. For example, based upon experimental data, although a default or nominal pitch for peaks between light concentrating elements is 5.6 mm, based upon five modules, the typical pitch has been approximately 5.7 mm. Additionally, based upon the current results, the typical minimum pitch has been approximately 5.50 mm and the typical maximum pitch has been approximately 5.75 mm. This translates to approximately a 5% variation in pitch. Based upon such data, it is calculated that the maximum angular offset from one exitant light beam to the adjacent exitant light beam is on the order of approximately +/−0.015 degrees. It was also discovered that overall, light concentrating elements/exitant light regions are not exactly parallel with the long axis of the glass. In some of the examples, the light concentrating elements were determined to be offset by approximately 0.001 degrees from the edge of the glass. The measurements described above, will of course be different between different batches of glass, different manufacturers of glass, and also by specific engineering design.

In various embodiments of the present invention, a PV panel is approximately rectangular in shape having dimensions of approximately 1014 mm by 1610 mm. In other embodiments, the dimensions may be approximately 1014 mm×1926 mm, or the like. It should be understood that in other embodiments, the shape and dimensions of the PV panel may be adjusted according to engineering or non-engineering requirements. In light of thermal expansion and contraction factors, the inventors of the present invention determined that PV strings should span the shorter dimension of the PV panel. More specifically, since the conducting crossbars of the PV string are longer than the length of each PV strip, the conducting crossbars are subject to greater changes in length than PV strips due to heating and cooling of the PV panel. Accordingly, in various embodiments, the PV strings (appearing similar to a picket fence) span the shorter dimension of a PV panel. In such embodiments, it is contemplated that the light concentrating elements of the substantially transparent material (e.g. glass) sheet extend in the longer dimension on the sheet of transparent material, while the PV strings extends across the shorter dimension across the sheet of transparent material.

In other embodiments, other adjustments to the placement of the PV strips may be performed to account for the reflow of the thin sheet of translucent/opaque material, described above. In particular, as was illustrated in the cross section 500 in FIG. 3C adhesive layers 620 and 625 are heated and compressed to result in the cross section 500 in FIG. 3D. In various embodiments, the combination of reflow and pressure are expected to impart a force outwards from approximately the middle of the PV panel towards the edges of the PV panel. Accordingly, in the example of FIG. 7, if PV strips 940 is to be located at the top left edge of a PV panel, PV strip 940 may be adjusted from having a left/right offset of 0% to +2% (rightwards) and an up/down offset of 0% to −1% (downwards), PV strip 950 may be adjusted from having a left/right offset of −21% to −19.5. % (rightwards) and an up/down offset of 0% to −1% (downwards), or the like. In another example, if PV strip 970 is to be located at the bottom right edge of a PV panel, PV strip 970 may be adjusted from having a left/right offset of 0% to −1.5% (leftwards), and an up/down offset of 0% to +2% (upwards), PV strip 960 may be adjusted from having a left/right offset of −6% to −7% offset (leftwards), and an up/down offset of 0% to +2% (upwards), or the like. In still another example, if PV strip 950 is to be located at approximately the upper middle of the PV panel, PV strip 940 may be adjusted from having a 0% offset to a +0.25% offset (rightwards), and may be adjusted from having a −0.8° angle to a −0.5° angle (e.g. moving the top edge to the left by 10 microns), PV strip 960 may be adjusted from having a −6% offset to a −6.25% offset (leftwards), and may be adjusted from having a −3.8° angle to having a −4.1° angle (e.g. moving the bottom edge to the left by 10 microns), PV strip 970 may be adjusted from having a 0% offset to a −0.25% offset (leftwards), and may be adjusted from having a 0° angle to having a −0.3° angle, or the like.

It should be understood that the above described adjustments to the placement of the PV strips are merely given for sake of explanation of the general principle. In various embodiments, the amount of adjustments may be larger or smaller, based typically upon experimental test results, simulations, or the like.

Returning to the discussion of FIG. 6, in various embodiments, multiple stages are illustrated for soldering station platform 930. In various embodiments, stages 1030, 1040 and 1050 are used for placement of PV strips, as described above. In some examples, stages 1030-1050 may each place four PV strips (to form a 12 PV strip PV assembly), eight PV strips (to form a 24 PV strip PV assembly), or a different number of PV strips. In other examples, stages 103-1050 may each place PV strips for a PV assembly (e.g. 14 PV strips for a 14 PV strip PV assembly).

In various embodiments, stages 1060 and 1070 may be used for placement and soldering of a crossbar conductor. Then, in stage 1060, one or more conductor bus bars may be positioned perpendicular to and on top of the placed PV strips. In various embodiments three conductor bars are used on one side of the PV strips, and in other embodiments, a different number of conductor bus bars are used. Further, in various embodiments, conductor bus bars may be used on both the top and/or bottom of PV strips. Subsequently, in stage 1070, a soldering head or soldering bar heats and solders the PV strips to the conductor bus bars to form a PV assembly.

In various embodiments, a pick and place robot 1080 then picks up PV assemblies and then places them onto a stage 1090. In various embodiments, the conductor bus bars of adjacent PV assemblies that are placed on stage 1090 overlap, i.e. in an over and under configuration where the conductor bus bar tail of one PV assembly is below a conductor bus bar head or below the PV strips of the next PV assembly, and the like. Subsequently, the PV assemblies are soldered (e.g. from below the PV strips) together with a soldering head or soldering bar to form a PV string, as described herein.

In various embodiments, a PV string may include any number of PV assemblies depending upon the size of the PV panel and the number of PV strips per assembly. In some examples, one PV string includes 14 PV assemblies that each include 12 PV strips; one PV string includes 7 PV assemblies that each include 24 PV strips; one PV string includes 12 PV assemblies that each include 14 PV strips, or the like, based upon a typical 5.80 mm pitch and 1014 mm width PV panel. In other embodiments, the number of PV strips that form a PV assembly may vary, such as 12, 16, 18, or the like, and the number of PV assemblies that form a PV string may also vary. In various embodiments, the PV strips are approximately on the order of 156 mm, or the like. Accordingly approximately 10 PV strings are typically used per PV panel.

In various embodiments of the present invention, after forming PV strings upon stage 1090, the energy conversion and/or electronic characteristics of the PV string may be characterized. In some embodiments, the PV strings are placed into a dark environment, and current characteristics of each PV string are determined based upon applied voltages applied to the conducting bus bars. As merely an example, a reverse voltage (current) may be applied starting from zero volts and swept downwards across the PV strips via the conducting bus bars, and the output current (voltage) is measure

d. Based upon the applied voltage (or current) and measured current (or voltage), the internal resistance of the PV strip is then determined: Rshunt, Rseries. Additionally, a series of positive voltages may be applied starting at zero volts and swept upwards across the PV strips. Based upon the measured responsive current, a determination may be made as to open circuit and short circuit conditions.

In various embodiments, the performance of each PV string is then tagged with the measured/determined characteristics. Subsequently, in various embodiments, PV strings having similar characteristics (e.g. internal resistance Rshunt, Rseries) can be electrically connected with conductors/bussing. In other embodiments, other types of characteristics may also be tested, such as output response to a uniform light source, response to a positive voltage and/or a positive current, and the like. As one example, a current may be applied across a PV sting (which appear as a series of diodes) and the voltage is increased up to some maximum voltage. The voltage applied that results in a current flowing, is then used to determine any open circuits or short circuits. As an example, if the PV string appear as five diodes. If the PV string does not conduct at the maximum voltage, this may indicate an open circuit condition. If the PV string conducts at approximately 2.4 volts (2.4 v=4×0.6 v), this may indicate that that two of the PV assemblies have a short circuit condition. If the PV string conducts at approximately 3 volts (3v=5×0.6v), the string may incorporated into a PV panel. In various embodiments, based upon the error condition, the PV strip may be pulled from the manufacturing line and discarded or repaired.

The inventors of the present invention believe that matching current and voltage performance of PV strings (e.g. Rseries, Rshunt) (and potentially of PV assemblies within PV strings) to be used for a PV panel, reduces the stress on mismatched PV strips, mismatched PV assemblies, and/or PV strings. Accordingly, the inventors believe such matching will increase the longevity of PV panels, by reducing hot spot, e.g. PV assemblies operating as a load in reverse bias.

Embodiments of the present invention are configured to have fewer PV strips be combined in into a PV assembly, and a larger number of PV assemblies combined into a PV string. This results in a lower current, higher voltage output for PV strings. In various embodiments, sets of four PV strings are wired in parallel to increase the current. This results in a high current, high voltage output for the PV module, although other arrangements are also imaginable. In various embodiments, by measuring and ensuring that the series resistances of the PV strings are relatively the same within a PV panel, this results in the production of some PV panels with uniformly lower Rseries and other PV panels with uniformly higher Rseries. Accordingly, some PV panels will have a higher power output and higher fill factors than other PV panels.

In various embodiments, the soldered PV strings 1100 are placed on top of an transparent adhesive layer that is on top of the optically concentrating piece of substantially transparent material. An example of this was illustrated by transparent sheet 510, adhesive layer 625, and PV string (e.g. 605, 600, 610, 615, etc.). In various embodiments, one or more fiducial marks on the transparent material may be referred to for proper alignment of the PV strings relative to the transparent material (e.g. glass) (based upon the optical characterization described above). In various embodiments, placement of the PV strings may be controlled in the x, y, and θ directions. In various embodiments PV strings may be produced by other PV stringing units, as illustrated in FIG. 6, in parallel, and provided for use in the same PV module 1120. For example, in various embodiments, four PV stringing units may be used. In various embodiments, 12 to 14 PV strings may be used per PV panel.

Next, one or more connecting bus bars may be used to electrically couple the PV strings together and/or to the PV panel output. Subsequently, additional adhesive layer 620 and backing layer 630 may be placed upon the interconnected PV strings to form a composite structure (e.g. PV structure) as illustrated in FIG. 3C. Then, as described above, a controlled pressure/heating process may then be applied to the composite structure to form the PV panel, as illustrated in FIG. 3D or 3E.

Further embodiments can be envisioned to one of ordinary skill in the art after reading this disclosure. In other embodiments, combinations or sub-combinations of the above disclosed invention can be advantageously made. The block diagrams of the architecture and flow charts are grouped for ease of understanding. However it should be understood that combinations of blocks, additions of new blocks, re-arrangement of blocks, and the like are contemplated in alternative embodiments of the present invention.

The specification and drawings are, accordingly, to be regarded in an illustrative rather than a restrictive sense. It will, however, be evident that various modifications and changes may be made thereunto without departing from the broader spirit and scope.

What is claimed is:

1. A light energy collection device comprising:
a transparent material having a plurality of light concentrating geometric features, wherein the plurality of light concentrating geometric features are configured to receive incident light and configured to output concentrated light at an associated plurality of exitant regions, the plurality of concentrating geometric features configured in a plurality of elongated structures arranged in a substantially parallel manner along a first direction from a first end to a second end of the transparent material, wherein at least two adjacent exitant regions are characterized by a non-uniform exitant pitch along the first direction, wherein the non-uniform exitant pitch varies from approximately 5.5 mm to approximately 5.8 mm along the first direction;
a non-uniform string of two or more photovoltaic strips, wherein the non-uniform string extends in a second direction from a third end to a fourth end of the transparent material, wherein the second direction is approximately orthogonal to the first direction, and wherein the non-uniform string comprises:
a plurality of conductive electrodes arranged in a substantially parallel manner along the second direction of the transparent material; and
a plurality of photovoltaic strips coupled to the plurality of conductive electrodes, wherein the plurality of photovoltaic strips are approximately oriented along the first direction, and wherein adjacent photovoltaic strips are characterized by a non-uniform photovoltaic strip pitch along the first direction in response to the non-uniform exitant pitch;
whereupon the plurality of photovoltaic strips of the non-uniform string of the two or more photovoltaic strips are configured to receive the concentrated light from the plurality of light concentrating geometric features and configured to output electrical energy in response to the concentrated light.

2. The device of claim 1
wherein the transparent material comprises a sheet of glass.

3. The device of claim 1
wherein the plurality of light concentrating geometric features configured to receive light and configured to output concentrated light comprises an upper shaped surface selected from a group consisting of: semicircular-shaped, triangular-shaped, and ovoid-shaped, and comprises a lower planar surface.

4. The device of claim 1
wherein the plurality of photovoltaic strips configured to receive the concentrated light includes an upper surface directed towards the plurality of light concentrating geometric features, and
wherein the plurality of photovoltaic strips configured to output electrical energy includes a lower surface, wherein a current is formed between the upper surface and the lower surface in response to the concentrated light.

5. The device of claim 1
wherein the non-uniform photovoltaic strip pitch along the first direction comprises a first PV strip pitch between a first end of a first photovoltaic strip and a first end of a second photovoltaic strip, and a second PV strip pitch between a second end of the first photovoltaic strip and a second end of the second photovoltaic strip, and
wherein the first PV strip pitch is different from the second PV strip pitch.

6. The device of claim 1
wherein the non-uniform photovoltaic strip pitch along the first direction comprises a non-zero angle between a first photovoltaic strip with respect to a second photovoltaic strip.

7. The device of claim 1 wherein a nominal exitant pitch is approximately 5.7 mm.

8. The device of claim 1 wherein a center line associated with an associated exitant region associated with a light concentrating geometric feature is angled relative to a centerline associated with the light concentrating geometric feature.

9. The device of claim 2
wherein the non-uniform photovoltaic strip pitch along the first direction varies from approximately 5.5 mm to approximately 5.8 mm along the first direction.

10. The device of claim 9
wherein the plurality of photovoltaic strips are soldered to the plurality of conductive electrodes; and
wherein the sheet of glass is adhered to the plurality of photovoltaic strips via the adhesive layer.

11. A light energy collection device comprising:
a transparent material having a plurality of light concentrating geometric features comprising a top surface configured to receive incident light and a bottom surface configured to output concentrated light at a plurality of exitant regions, wherein the plurality of light concentrating geometric features comprise elongated structures arranged in a substantially parallel manner along a first axis relative to the transparent material, wherein a first exitant region and a second exitant region from the plurality of exitant regions are characterized by an exitant separation pitch along a second axis relative to the transparent material, that is non-uniform along the first axis, wherein the exitant separation pitch varies by no more than approximately 5% from a nominal separation pitch, and wherein the first axis is approximately orthogonal to the second axis;
a string of two or more photovoltaic strips disposed below the transparent material, wherein the string extends along the second axis relative to the transparent material, wherein the string comprises:
a plurality of conductive electrodes arranged in a substantially parallel manner along the second axis of the transparent material; and
a plurality of photovoltaic strips coupled to the plurality of conductive electrodes, wherein the plurality of photovoltaic strips are approximately oriented along the first axis, and wherein a first photovoltaic strip and a second photovoltaic strip from the plurality of photovoltaic strips are characterized by a PV separation pitch along the second axis relative to the transparent material, that is non-uniform along the first axis, and in response to the exitant separation pitch; and
wherein the plurality of photovoltaic strips are positioned to receive the concentrated light and output electrical energy in response thereto.

12. The device of claim 11 wherein the transparent material comprises a sheet of glass.

13. The device of claim 11 wherein the top surface comprises a shaped selected from a group consisting of: semicircular-shaped, triangular-shaped, and ovoid-shaped, and comprises a lower planar surface.

14. The device of claim 11 wherein the plurality of photovoltaic strips comprise:
a lower p-type region; and
an upper n-type region positioned to receive the concentrated light output;
wherein the plurality of photovoltaic strips output electrical energy relative to the lower p-type region and the upper n-type region in response to the concentrated light.

15. The device of claim 11
wherein the PV separation pitch along the second axis comprises a first PV separation pitch between a first end of the first photovoltaic strip and a first end of the second photovoltaic strip, and a second PV separation pitch between a second end of the first photovoltaic strip and a second end of the second photovoltaic strip, and
wherein the first PV separation pitch is different from the second PV separation pitch by no more than approximately 5%.

16. The device of claim 11
wherein the PV separation pitch along the second axis relative to the transparent material, that is non-uniform along the first axis comprises, a non-zero angle between the first photovoltaic strip with respect to the second photovoltaic strip.

17. The device of claim 11 wherein the non-zero angle is no more than approximately 0.03 degrees.

18. The device of claim 11 wherein the nominal exitant pitch is approximately 5.7 mm.

19. The device of claim 11
wherein the exitant separation pitch along the second axis relative to the transparent material, that is non-uniform along the first axis comprises, a non-zero angle between the first exitant region and the second exitant region;
wherein the non-zero angle is no more than approximately 0.02 degrees.

20. The device of claim 11 wherein the plurality of photovoltaic strips are soldered to the plurality of conductive electrodes; and
wherein the sheet of glass is adhered to the plurality of photovoltaic strips via the adhesive layer.
